(19) United States
(12) Patent Application Publication
(10) Pub. No.: US 2010/0258167 A1
(43) Pub. Date: Oct. 14, 2010

(54) PHOTOVOLTAIC CELL STRUCTURE AND MANUFACTURING METHOD

(75) Inventors: FENG FAN CHANG, KAOHSIUNG CITY (TW); HSIN CHIH LIN, TAICHUNG CITY (TW); HSIN HUNG LIN, YILAN COUNTY (TW); CHI HAU HSIEH, KAOHSIUNG CITY (TW); TZUNG ZONE LI, YUNLIN COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: PVNEXT CORPORATION, HSINCHU (TW)

(21) Appl. No.: 12/756,804

(22) Filed: Apr. 8, 2010

(30) Foreign Application Priority Data
Apr. 10, 2009 (TW) 098111922

(51) Int. Cl. H01L 31/00

(52) U.S. Cl. 136/254; 136/256

(57) ABSTRACT

A photovoltaic cell structure includes a substrate, a metal layer, a p-type semiconductor layer, an n-type semiconductor layer, a high resistivity layer, an assistant electrode layer, and a transparent conductive layer. The metal layer is formed on the substrate, and comprises a plurality of p-type electrode units separated from each other. The p-type semiconductor layer is formed on the metal layer. The n-type semiconductor is formed on the p-type semiconductor layer, thereby forming a p-n junction. The high resistivity layer is formed on the n-type semiconductor layer. The assistant electrode layer is formed on the high resistivity layer and the p-type electrode units. The transparent conductive layer is formed on the assistant electrode layer, the high resistivity layer and the p-type electrode units. Accordingly, at least one cell is formed on each of the p-type electrode units. The assistant electrode layer and the transparent conductive layer are connected to the cells in series.

### BACKGROUND OF THE INVENTION

(A) Field of the Invention

The present invention relates to a photovoltaic cell structure and a manufacturing method thereof, and more specifically, to a four-element thin-film photovoltaic cell structure including Copper Indium Gallium Diselenide (CIGS).

(B) Description of the Related Art

Normally, copper Indium Gallium Diselenide thin-film solar cells are one of two types; one type is comprised of copper, indium and selenium, and the other type is comprised of copper, indium, gallium and selenium. Because of the high photoelectrical efficiency and low material cost, solar cell development is expected to continue at a rapid pace. The photoelectrical efficiency of CIGS solar cells in the laboratory can reach around 19%, and 13% for related solar cell modules.

FIG. 1 shows a traditional CIGS photovoltaic cell structure 10 disclosed by U.S. Pat. No. 5,948,176, which is a laminate structure. The photovoltaic cell structure 10 includes a substrate 11, a metal layer 12, a CIGS layer 13, a buffer layer 14, a high-resistance film layer 15, a transparent conductive layer (TCO) 16, and an assistant electrode layer 17. The substrate 11 may be a glass substrate, and the metal layer 12 may be a molybdenum metal layer to comply with the chemical characteristics of CIGS and to withstand high temperature while the CIGS layer 13 is deposited. The CIGS layer 13 is a p-type semiconductor layer. The buffer layer 14, which is an n-type semiconductor layer that may be made of cadmium sulfate (CdS), and the CIGS layer 13 form a p-n junction therebetween. The high-resistance film layer 15 may be a zinc oxide (ZnO) layer, and the transparent conductive layer 16 may be zinc oxide (ZnO) with doped aluminum (AZO) or the like. The transparent conductive layer 16 is also called a window layer, and allows light to penetrate and reach the CIGS layer 13 beneath it.

Compared with metal, the resistance of the transparent conductive layer 16 is high, so the assistant electrode layer 17 is formed on the transparent conductive layer 16. The assistant electrode layer 17 includes a plurality of slender metal strips, which minimize shielded light to maintain maximum light energy absorption. However, the assistant electrode layer 17 is formed on the transparent conductive layer 16, and hence, current still passes through the transparent conductive layer 16 with high resistance and then passes through the assistant electrode layer 17 with low resistance. Consequently, the assistant electrode layer 17 cannot effectively reduce the entire resistance of the photovoltaic cell structure 10.

### SUMMARY OF THE INVENTION

The present invention provides a photovoltaic cell structure and a manufacturing method thereof. An assistant electrode layer is disposed beneath a transparent conductive layer, and both the contact resistance between them and their total resistance are reduced. That is, the electrical conductivity of the n-type electrode is improved so as to increase the output of electrical energy from the photovoltaic cell structure.

In accordance with an embodiment of the present invention, a photovoltaic cell structure includes a substrate, a metal layer, a p-type semiconductor layer, an n-type semiconductor layer, a high resistivity layer, an assistant electrode layer, and a transparent conductive layer. The metal layer is formed on the substrate and comprises a plurality of p-type electrode units separated from each other. The p-type semiconductor layer is formed on the metal layer. The n-type semiconductor is formed on the p-type semiconductor layer, forming a p-n junction. The high resistivity layer is formed on the n-type semiconductor layer. The assistant electrode layer is formed on the high resistivity layer and the p-type electrode units. The transparent conductive layer is formed on the assistant electrode layer, the high resistivity layer and the p-type electrode units. Accordingly, at least one cell is formed on each of the p-type electrode units. The assistant electrode layer and the transparent conductive layer are connected to the cells in series.

In accordance with another embodiment of the present invention, a photovoltaic cell structure includes a substrate, a metal layer, a high resistivity layer, a p-type semiconductor layer, an n-type semiconductor layer, an assistant electrode layer, and a transparent conductive layer. The metal layer is formed on the substrate, and comprises a plurality of p-type electrode units separated from each other. The high resistivity layer is formed on the metal layer. The p-type semiconductor layer is formed on the high resistivity layer. The n-type semiconductor is formed on the p-type semiconductor layer, thereby forming a p-n junction. The assistant electrode layer is formed on the n-type semiconductor layer and the p-type electrode units. The transparent conductive layer is formed on the assistant electrode layer, the high resistivity layer and the p-type electrode units. Accordingly, at least one cell is formed on each of the p-type electrode units. The assistant electrode layer and the transparent conductive layer are connected to the cells in series.

In accordance with another embodiment of the present invention, a method for manufacturing a photovoltaic cell structure comprises steps of: providing a substrate; forming a metal layer having a plurality of p-type electrode units separated from each other on the substrate; forming a p-type semiconductor layer on the metal layer; forming an n-type semiconductor on a surface of the p-type semiconductor layer; forming an assistant electrode layer above the n-type semiconductor layer and on surfaces of the p-type electrode units; and forming a transparent conductive layer above the n-type semiconductor layer and on surfaces of the assistant electrode layer and the p-type electrode units; wherein at least one cell is formed on each of the p-type electrode units, and the assistant electrode layer and the transparent conductive layer connect the cells.

In accordance with another embodiment of the present invention, the method further comprises a step of: forming a high resistivity layer on the n-type semiconductor layer.

In accordance with another embodiment of the present invention, the method further comprises a step of: forming a high resistivity layer on a surface of the metal layer.

### BRIEF DESCRIPTION OF THE DRAWINGS

FIG. 1 shows a known photovoltaic cell structure disclosed by U.S. Pat. No. 5,948,176;

FIGS. 2A to 2I show the method for manufacturing a photovoltaic cell structure in accordance with an embodiment of the present invention; and

FIGS. 3A to 3I show the method for manufacturing a photovoltaic cell structure in accordance with another embodiment of the present invention.

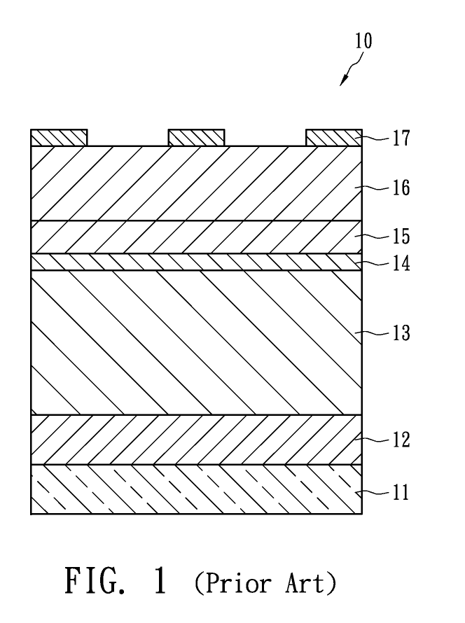

### DETAILED DESCRIPTION OF THE INVENTION

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

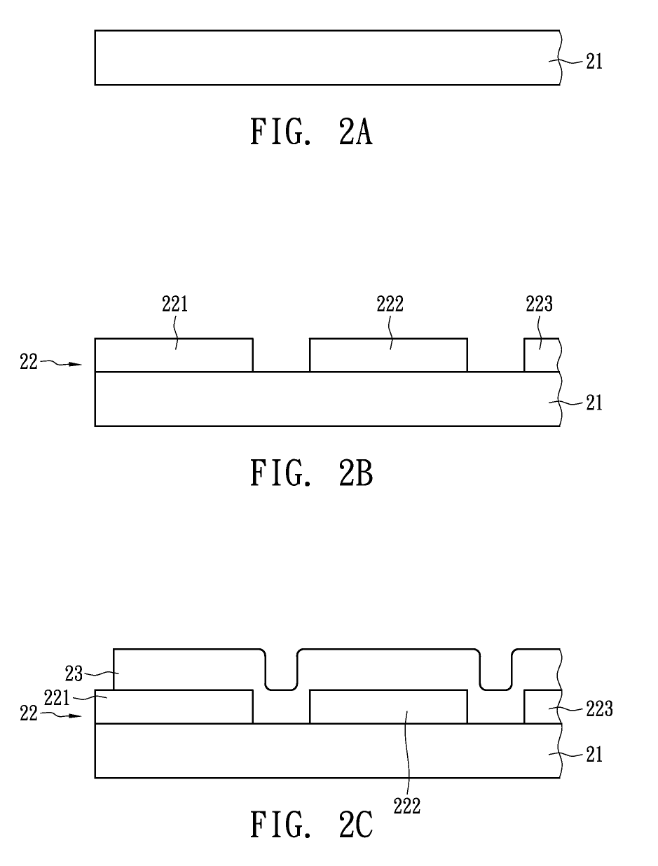

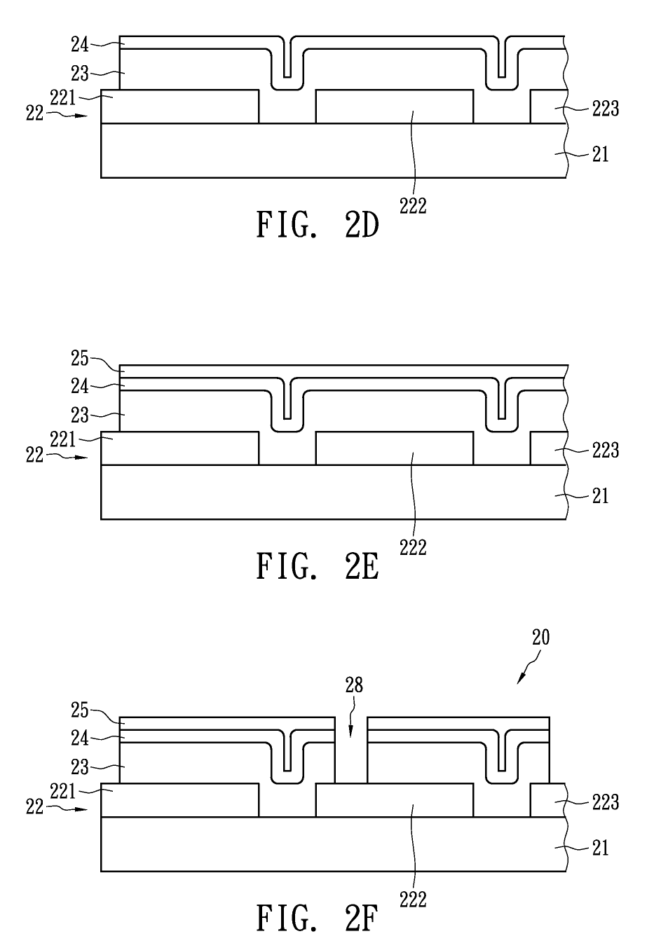

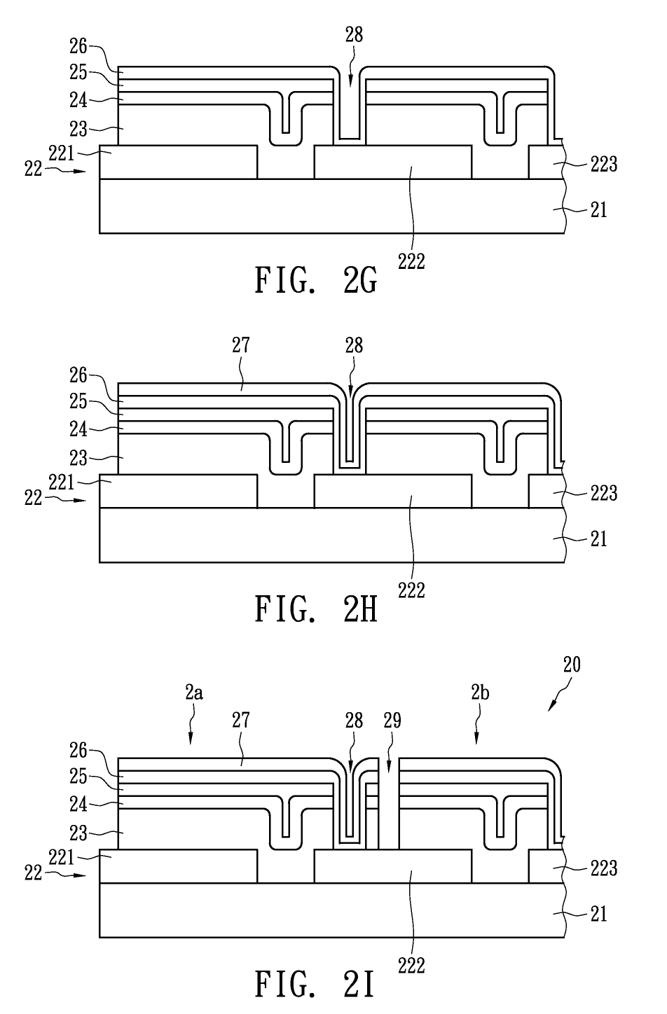

FIGS. 2A to 2I show a method for manufacturing a photovoltaic cell structure in accordance with an embodiment of the present invention. As shown in FIG. 2A, a substrate 21 for carrying a photovoltaic cell structure is provided. In addition to a glass substrate, the substrate 21 may be a polyimide flexible substrate, or a metal plate or a metal foil of stainless steel, molybdenum, copper, titanium or aluminum. The substrate 21 is not limited by the plate-like profile of the embodiment, and cannot be merely considered as a film support. For example, the substrate with a ball-like profile, a specified profile, or an irregular profile is also used by the present invention.

A metal layer 22 is formed on the substrate 21 using wet etching, dry etching, or laser cutting, and the metal layer 22 is divided into a plurality of p-type electrode units 221, 222, and 223 separated from each other, as shown in

FIG. 2B. The metal layer 22 may be a metal layer of molybdenum, chromium, vanadium or tungsten, and may have a thickness between 0.5 to 1 micrometers. The metal layer 22 is formed on the substrate 21 to be a back contact metal layer of the cell.

As shown in FIG. 2C, a p-type semiconductor layer 23 is formed on surfaces of the metal layer 22 and the substrate 21, and may include a compound of copper indium gallium selenium sulfur (CIGSS), copper indium gallium selenium (CIGS), copper indium sulfur (CIS), copper indium selenium (CIS) or a compound of at least two of copper, selenium or sulfur. The thickness of the p-type semiconductor layer 23 may be between 0.5 and 4 micrometers. As shown in FIG. 2D, an n-type semiconductor layer 24 is formed on the p-type semiconductor layer 23, thereby forming a p-n junction therebetween. In an embodiment, the n-type semiconductor layer 24 may be cadmium sulfate (CdS), zinc sulfate (ZnS) or indium sulfate (InS).

As shown in FIG. 2E, a high resistivity layer 25 is formed on the n-type semiconductor layer 24 and has a thickness between 25 and 2000 angstroms. The material of the high resistivity layer 25 is metal oxide or metal nitride. The metal oxide may be vanadium oxide, tungsten oxide, molybdenum oxide, copper oxide, iron oxide, tin oxide, titanium oxide, zinc oxide, zirconium oxide, lanthanum oxide, niobium oxide, indium tin oxide, strontium oxide, cadmium oxide, indium oxide, or a compound or an alloy of one or more aforesaid metals. Furthermore, other materials for the insulating material of a capacitor can also be used as the material of the high resistivity layer 25, such as silicon, alumina or the like. As shown in FIG. 2F, the laminated layers on the metal layer 22 are cut to form a plurality of divisional grooves 28, and the p-type electrode units 222 and 223 are exposed.

As shown in FIG. 2G, an assistant electrode layer 26 is formed on the high resistivity layer 25 and the p-type electrode units 222 and 223. The assistant electrode layer 26 has a plurality of slender metal strips, or metal wires of any slender shape, which minimize shielded light to maintain maximum light energy absorption. The assistant electrode layer 26 can be formed by mask vapor deposition, mask sputtering, metal etching or screen printing. That is, silver, tin, indium, zinc, or copper is deposited or coated on the high resistivity layer 25 and the metal layer 22.

As shown in FIG. 2H, a transparent conductive layer 27 is formed on surfaces of the assistant electrode layer 26, the high resistivity layer 25 and the p-type electrode units 222 and 223 (the assistant electrode layer 26 does not fully cover surfaces of the high resistivity layer 25 and the p-type electrode units 222 and 223). The assistant electrode layer 26 and the transparent conductive layer 27 are sequentially filled in the divisional groove 28, and both of them contact the p-type electrode units 222 and 223. Thereafter, the laminated layers on the metal layer 22 are cut to form a plurality of divisional grooves 29, and the p-type electrode units 222 and 223 are exposed. Consequentially, at least one cell (2a or 2b) is formed on each of the p-type electrode units 221 and 222, and the assistant electrode layer 26 and the transparent conductive layer 27 connect the cells 2a and 2b, as shown in FIG. 2I. In this embodiment, the assistant electrode layer 26 is beneath the transparent conductive layer 27, and both the contact resistance between them and their total resistance are reduced. Accordingly, the electrical conductivity of the n-type electrode (the transparent conductive layer 27) is also increased so as to improve the output of electrical energy from the photovoltaic cell structure 20. The transparent conductive layer 27 may be indium tin oxide (ITO), indium zinc oxide (IZO), aluminum zinc oxide (AZO), gallium zinc oxide (GZO), aluminum gallium zinc oxide (GAZO), cadmium tin oxide (CTO), zinc oxide (ZnO) and zirconium dioxide (ZrO₂) or other transparent conductive materials.

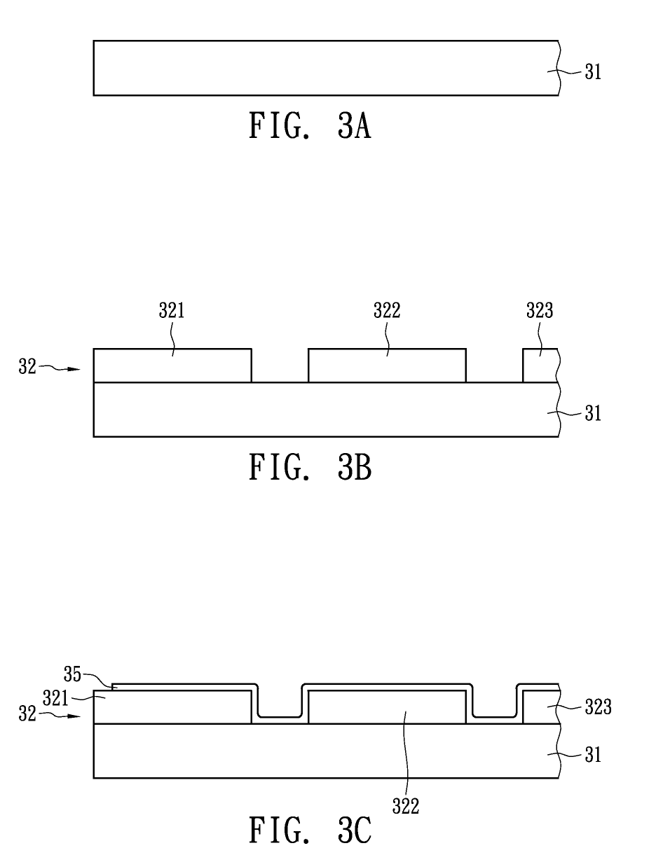

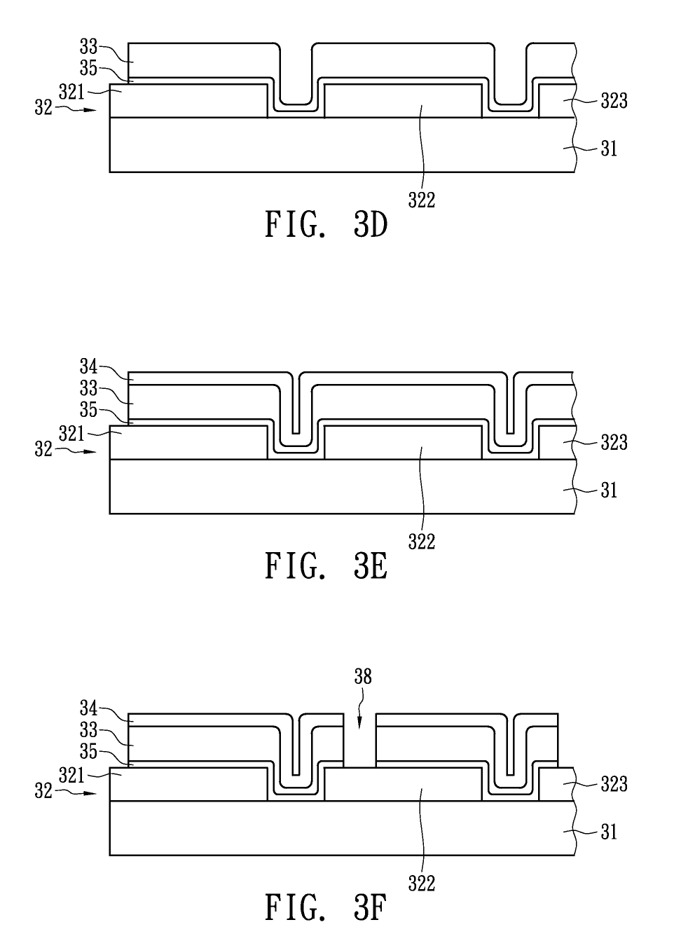

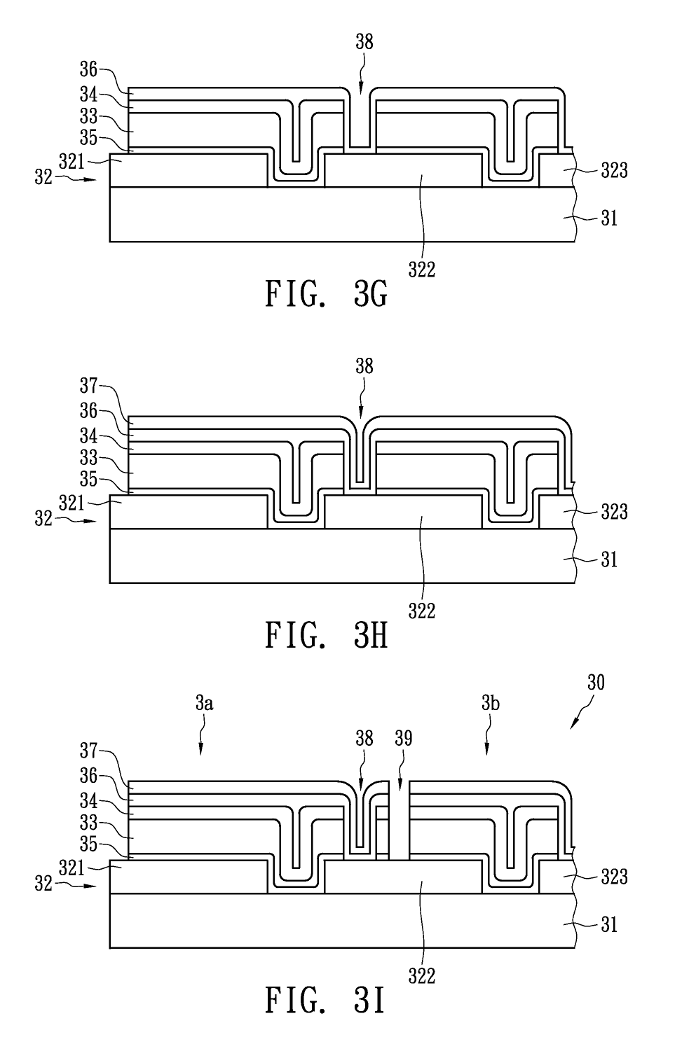

FIGS. 3A to 3I show the method for manufacturing a photovoltaic cell structure in accordance with another embodiment of the present invention. As shown in FIG. 3A, a substrate 31 for carrying a photovoltaic cell structure is provided. A metal layer 32 is formed on the substrate 32 using wet etching, dry etching, or laser cutting, and the metal layer 32 is divided into a plurality of p-type electrode units 321, 322, and 323 separated from each other, as shown in FIG. 3B. The metal layer 32 may be a metal layer of molybdenum, chromium, vanadium or tungsten, and may have a thickness between 0.5 to 1 micrometers. The metal layer 22 is formed on the substrate 31 to be a back contact metal layer of the cell.

As shown in FIG. 3C, a high resistivity layer 35 is formed on surfaces of the metal layer 32 and the substrate 31, and has a thickness between 25 and 2000 angstroms. The material of the high resistivity layer 25 is metal oxide or metal nitride.

As shown in FIG. 3D, a p-type semiconductor layer 33 is formed on a surface of the high resistivity layer 35, and may include a compound of copper indium gallium selenium sulfur (CIGSS), copper indium gallium selenium (CIGS), copper indium sulfur (CIS), copper indium selenium (CIS) or a compound of at least two of copper, selenium or sulfur. The thickness of the p-type semiconductor layer 33 may be between 0.5 and 4 micrometers. As shown in FIG. 3E, an n-type semiconductor layer 34 such as cadmium sulfate (CdS) is formed on the p-type semiconductor layer 33, thereby forming a p-n junction therebetween. As shown in FIG. 3F, the laminated layers on the metal layer 32 are cut to form a plurality of divisional grooves 38, and the p-type electrode units 322 and 323 are exposed.

As shown in FIG. 3F, an assistant electrode layer 36 is formed on the n-type semiconductor layer 34 and the p-type electrode units 322 and 323. The assistant electrode layer 36 has a plurality of slender metal strips, or metal wires of any slender shape, which minimize shielded light to maintain maximum light energy absorption. Alternatively, the assistant electrode layer 36 of any shape can be configured to cover 0.01% to 10% of the effective light absorption area of the photovoltaic cell structure. The assistant electrode layer 36 can be formed by mask vapor deposition, mask sputtering, metal etching or screen printing. That is, silver, tin, indium, zinc, or copper is deposited or coated on the n-type semiconductor layer 34 and the metal layer 32.

As shown in FIG. 3H, a transparent conductive layer 37 is formed on surfaces of the assistant electrode layer 36, the n-type semiconductor layer 34 and the p-type electrode units 222 and 223 (the assistant electrode layer 36 does not fully cover surfaces of the n-type semiconductor layer 34 and the p-type electrode units 322 and 323). The assistant electrode layer 36 and the transparent conductive layer 37 are sequentially filled in the divisional groove 38, and both of them contact the p-type electrode units 322 and 323. Thereafter, the laminated layers on the metal layer 32 are further cut to form a plurality of divisional grooves 39, and the p-type electrode units 322 and 323 are exposed. Consequentially, at least one cell (3a or 3b) is formed on each of the p-type electrode units 321 and 322, and the assistant electrode layer 36 and the transparent conductive layer 37 connect the cells 3a and 3b, as shown in FIG. 3I. In this embodiment, the assistant electrode layer 36 is beneath the transparent conductive layer 37, and both the contact resistance between them and their total resistance are reduced. Accordingly, the electrical conductivity of the n-type electrode (the transparent conductive layer 37) is increased so as to improve the output of electrical energy from the photovoltaic cell structure 30.

The above-described embodiments of the present invention are intended to be illustrative only. Numerous alternative embodiments may be devised by those skilled in the art without departing from the scope of the following claims.

What is claimed is:

1. A photovoltaic cell structure, comprising:
a substrate;
a metal layer formed on the substrate and including a plurality of p-type electrode units separated from each other;
a p-type semiconductor layer formed on the metal layer;
an n-type semiconductor layer formed on the p-type semiconductor layer,
a high resistivity layer formed on the n-type semiconductor layer;
an assistant electrode layer formed on the high resistivity layer and the p-type electrode units; and
a transparent conductive layer formed on the assistant electrode layer, the high resistivity layer and the p-type electrode units;
wherein at least one cell is formed on each of the p-type electrode units, and the assistant electrode layer and the transparent conductive layer are connected to the cells in series.

2. The photovoltaic cell structure of claim 1, wherein the n-type semiconductor layer comprises cadmium sulfate, zinc sulfate or indium sulfate.

3. The photovoltaic cell structure of claim 1, wherein the thickness of the n-type semiconductor layer ranges from 1 nm to 1,000 nm.

4. The photovoltaic cell structure of claim 1, wherein the high resistivity layer is interposed between the metal layer and the p-type semiconductor layer or between the n-type semiconductor layer and the transparent conductive layer.

5. The photovoltaic cell structure of claim 1, wherein the high resistivity layer comprises metal oxide.

6. The photovoltaic cell structure of claim 5, wherein the metal oxide is selected from the group consisting of vanadium oxide, tungsten oxide, molybdenum oxide, copper oxide, iron oxide, tin oxide, titanium oxide, zinc oxide, zirconium oxide, lanthaium oxide, niobium oxide, indium tin oxide, strontium oxide, cadmium oxide, indium oxide, or a mixture or alloy thereof.

7. The photovoltaic cell structure of claim 1, wherein the high resistivity layer comprises insulation material having capacitive effect.

8. The photovoltaic cell structure of claim 7, wherein the insulation material is silicon or aluminum oxide.

9. The photovoltaic cell structure of claim 1, wherein the high resistivity layer comprises metal nitride.

10. The photovoltaic cell structure of claim 1, wherein the high resistivity layer has a thickness between 25 and 2000 angstroms.

11. The photovoltaic cell structure of claim 1, wherein the transparent conductive layer comprises indium tin oxide, indium zinc oxide, aluminum zinc oxide, gallium zinc oxide, aluminum gallium zinc oxide, cadmium tin oxide, zinc oxide or zirconium dioxide.

12. The photovoltaic cell structure of claim 1, wherein the metal layer comprises molybdenum, chromium, vanadium and tungsten.

13. The photovoltaic cell structure of claim 1, wherein the substrate is a glass substrate, a polyimide flexible substrate, a metal plate or foil of stainless steel, molybdenum, copper, titanium or aluminum.

14. The photovoltaic cell structure of claim 1, wherein the assistant electrode layer includes a plurality of slender metal strips, or metal wires with a slender shape.

15. The photovoltaic cell structure of claim 1, wherein the material of the assistant electrode layer is silver, aluminum, or copper.

16. A photovoltaic cell structure, comprising:
a substrate;
a metal layer formed on the substrate and including a plurality of p-type electrode units separated from each other;
a high resistivity layer formed on the metal layer;
a p-type semiconductor layer formed on the high resistivity layer;
an n-type semiconductor layer formed on the p-type semiconductor layer,
an assistant electrode layer formed on the n-type semiconductor layer and the p-type electrode units; and
a transparent conductive layer formed on the assistant electrode layer, the n-type semiconductor layer and the p-type electrode units;
wherein at least one cell is formed on each of the p-type electrode units, and the assistant electrode layer and the transparent conductive layer are connected to the cells in series.

17. The photovoltaic cell structure of claim 16, wherein the n-type semiconductor layer comprises cadmium sulfate, zinc sulfate or indium sulfate.

18. The photovoltaic cell structure of claim 16, wherein the thickness of the n-type semiconductor layer ranges from 1 nm to 1,000 nm.

19. The photovoltaic cell structure of claim 16, wherein the high resistivity layer is interposed between the metal layer and the p-type semiconductor layer or between the n-type semiconductor layer and the transparent conductive layer.

20. The photovoltaic cell structure of claim 16, wherein the high resistivity layer comprises metal oxide.

21. The photovoltaic cell structure of claim 20, wherein the metal oxide is selected from the group consisting of vanadium oxide, tungsten oxide, molybdenum oxide, copper oxide, iron oxide, tin oxide, titanium oxide, zinc oxide, zirconium oxide, lanthaium oxide, niobium oxide, indium tin oxide, strontium oxide, cadmium oxide, indium oxide or a mixture or alloy thereof.

22. The photovoltaic cell structure of claim 16, wherein the high resistivity layer comprises insulation material having capacitive effect.

23. The photovoltaic cell structure of claim 22, wherein the insulation material is silicon or aluminum oxide.

24. The photovoltaic cell structure of claim 16, wherein the high resistivity layer comprises metal nitride.

25. The photovoltaic cell structure of claim 16, wherein the high resistivity layer has a thickness between 25 and 2000 angstroms.

26. The photovoltaic cell structure of claim 16, wherein the transparent conductive layer comprises indium tin oxide, indium zinc oxide, aluminum zinc oxide, gallium zinc oxide, aluminum gallium zinc oxide, cadmium tin oxide, zinc oxide or zirconium dioxide.

27. The photovoltaic cell structure of claim 16, wherein the metal layer comprises molybdenum, chromium, vanadium and tungsten.

28. The photovoltaic cell structure of claim 16, wherein the substrate is a glass substrate, a polyimide flexible substrate, a metal plate or foil of stainless steel, molybdenum, copper, titanium or aluminum.

29. The photovoltaic cell structure of claim 16, wherein the assistant electrode layer includes a plurality of slender metal strips, or metal wires with a slender shape which cover 0.01% to 10% of the effective light absorption area of the photovoltaic cell structure.

30. The photovoltaic cell structure of claim 16, wherein the material of the assistant electrode layer is silver, aluminum, or copper.
